(19) United States
(12) Patent Application Publication
(10) Pub. No.: US 2005/0146446 A1
(43) Pub. Date: Jul. 7, 2005

(54) Keyboards

(75) Inventor: Chien-Shih Hsu, Taipei (TW)

Correspondence Address: QUINTERO LAW OFFICE, 1617 BROADWAY, 3RD FLOOR, SANTA MONICA, CA, 90404, US

(73) Assignee: DARFON ELECTRONICS CORP., TAOYUAN (TW)

(21) Appl. No.: 11/019,562

(22) Filed: Dec. 21, 2004

(30) Foreign Application Priority Data
Jan. 7, 2004 (TW) TW93200226

(51) Int. Cl. H03M 11/00; H03K 17/94; H03C 1/00; G10H 1/04; G10H 7/00

(52) U.S. Cl. 341/22

(57) ABSTRACT

Keyboards. A keyboard includes a first key module, a second key module and a third key module. The second key module is pivotally connected to the first key module. The third key module is pivotally connected to the second key module. When the keyboard is folded, the third key module is situated between the first and the second key modules. When the keyboard is unfolded, the first, second and third key modules are situated substantially on the same plane.

### BACKGROUND

The invention relates in general to keyboards and in particular to portable folding keyboards.

Referring to FIG. 1a, a conventional folding keyboard with double-fold structure comprises a left key module L, a right key module R, a holder H and a hinge S. The keyboard can be frontally folded by rotating the left and right key modules L and R via the hinge S. The holder H is movably connected to the left key module L or the right key module R for supporting a portable electronic device, such as a PDA. The folding keyboard can be double-folded and miniaturized to half the original volume, however, the holder H must be shifted to the center to provide better viewing angle when the keyboard is unfolded for use as shown in FIG. 1a, and is inconvenient.

Referring to FIG. 1b, a conventional quadruple-fold keyboard includes a first, second, third and fourth key modules A1, A2, A3 and A4. It may be difficult, however, to fold and unfold due to the complex mechanism. As shown in FIG. 1b, some key units B protrude from the second and third modules A2 and A3 when the keyboard is folded, and may result in damage and unexpected impact from other portions of the keyboard. Moreover, the quadruple-fold keyboard in FIG. 1b is thicker than the double-fold keyboard, and dust may easily collect in the spaces among the key units.

### SUMMARY

Keyboards are provided. An exemplary embodiment of a keyboard includes a first key module, a second key module and a third key module. The second key module is pivotally connected to the first key module. The third key module is pivotally connected to the second key module. When the keyboard is folded, the third key module is situated between the first and the second key modules. When the keyboard is unfolded, the first, second and third key modules are situated on substantially the same plane.

### DESCRIPTION OF THE DRAWINGS

FIG. 1a is a perspective diagram of a conventional keyboard with double-fold structure;

FIG. 1b is another perspective diagram of a conventional keyboard with quadruple-fold structure;

FIG. 2 is an exploded diagram of an exemplary embodiment of a keyboard;

FIG. 3a is a perspective diagram of the keyboard in FIG. 2 unfolded;

FIGS. 3b and 3c are sectional views of the keyboard in FIG. 3a;

FIGS. 4a and 4b are perspective diagrams of an exemplary embodiment of a second key module and a third key module frontally folded;

FIG. 4c is a sectional view of an exemplary embodiment of a link slanted with respect to the second and third bases;

FIG. 5a is a perspective diagram of an exemplary embodiment of a first key module folded toward a third key module;

FIG. 5b is a sectional view of an exemplary embodiment of a keyboard completely folded;

FIG. 6 is an exploded diagram of an exemplary embodiment of a keyboard;

FIGS. 7a and 7b are perspective diagrams of an exemplary embodiment of a second key module and a third key module frontally folded;

FIG. 7c is a perspective diagram of an exemplary embodiment of a holder folded toward a second key module;

FIG. 7d is a perspective diagram of an exemplary embodiment of a first key module folded toward a third key module; and

FIG. 7e is a perspective diagram of an exemplary embodiment of a keyboard completely folded.

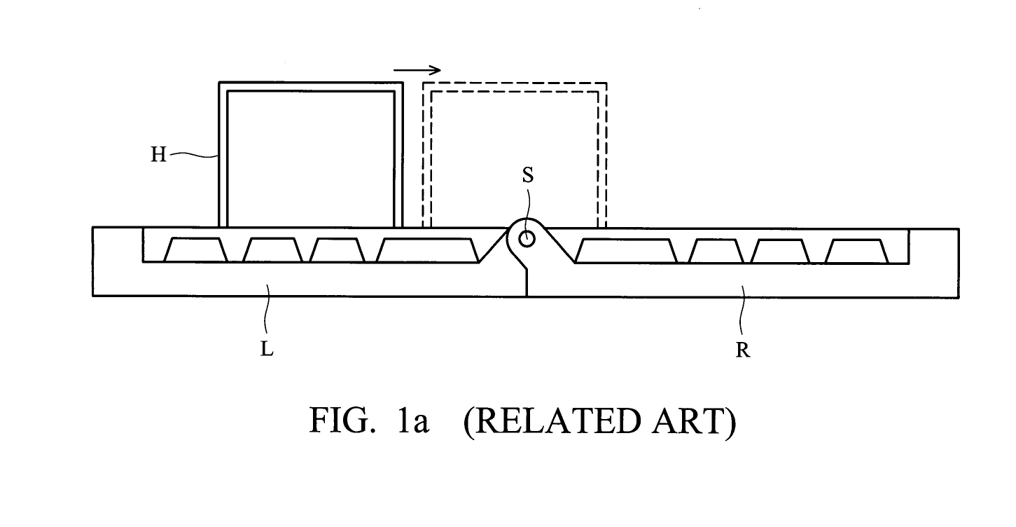

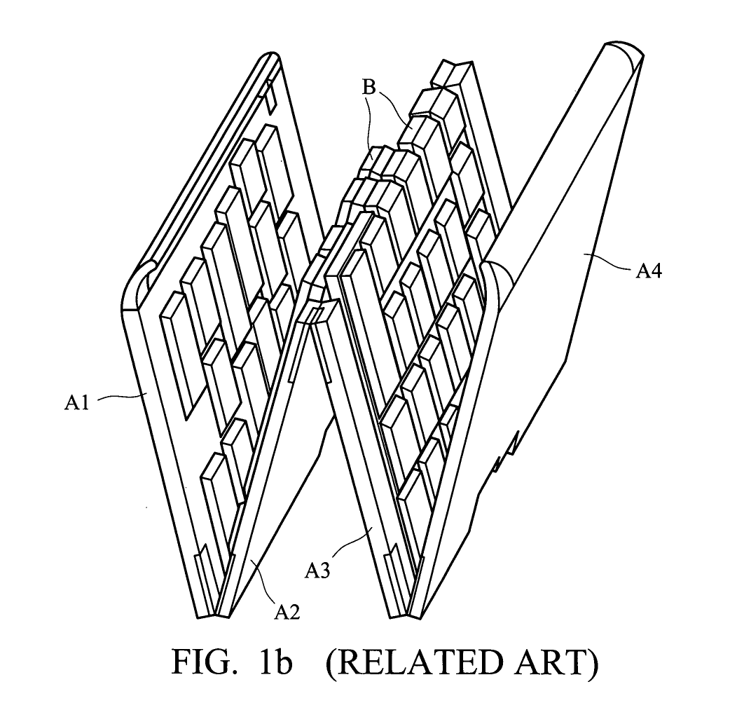

### DETAILED DESCRIPTION

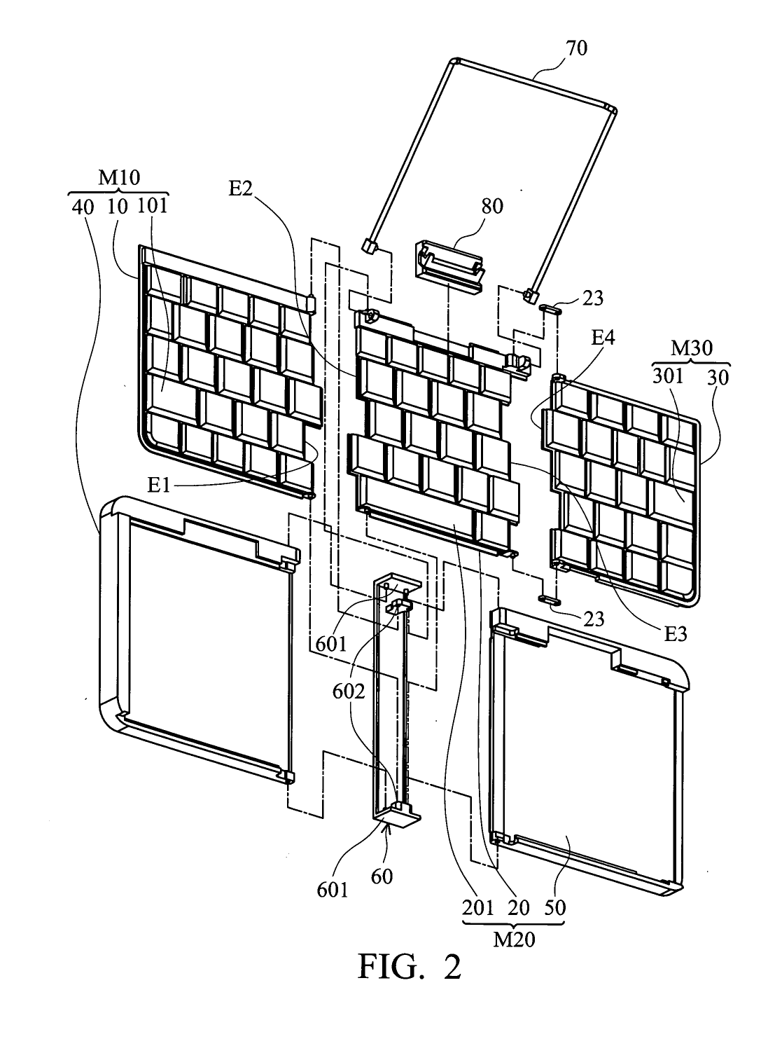

Referring to FIG. 2, an exemplary embodiment of a folding keyboard with a triple-fold structure primarily comprises a first key module M10, a second key module M20, a third key module M30, a coupler 60, a detachable holder 70 and a connector 80. The first key module M10 comprises a first enclosure 40, a first base 10 and a plurality of first key units 101 disposed on the first base 10. The second key module M20 comprises a second enclosure 50, a second base 20 and a plurality of second key units 201 disposed on the second base 20. The third key module M30 comprises a third base 30 and a plurality of third key units 301 disposed on the third base 30.

As shown in FIG. 2, the first and second enclosures 40 and 50 are pivotally connected to a first pivot portion 601 of the connector 60. The first and second bases 10 and 20, movably disposed in the first and second enclosure 40 and 50, are pivotally connected to a second pivot portion 602 of the coupler 60. When the first key module M10 is frontally folded toward the second key module M20, the first and second bases 10 and 20 slides in the first and second enclosures 40 and 50 respectively. The second and third bases 20 and 30 are pivotally connected via links 23, such that the third key module M30 is rotatable with respect to the second key module M20.

In FIG. 2, the first key units 101 projecting from the first base 10 form a first ragged edge E1, and the third key units 301 projecting from the third base 30 form a fourth ragged edge E4. Correspondingly, the second key units 201 projecting from the second base 20 form a second ragged edge E2 according to the first ragged edge E1, and a third ragged edge E3 according to a fourth ragged edge E4.

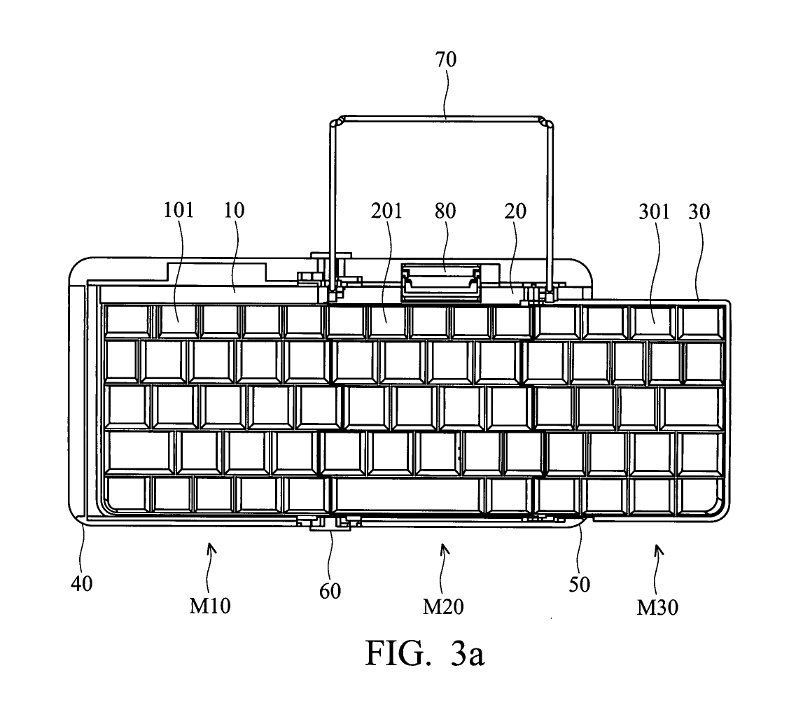

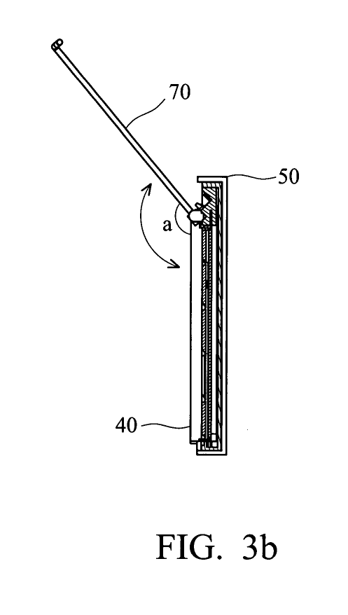

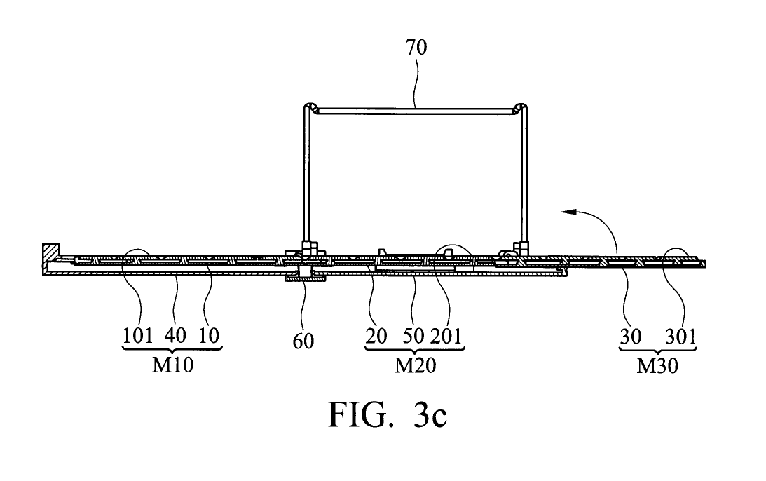

Referring to FIGS. 3a. 3b and 3c, the first, second and third key modules M10, M20 and M30 are substantially situated in the same plane when the keyboard is unfolded. The connector 80 is disposed on the second base 20 for electrically connecting a portable electric device, such as a PDA. The holder 70 are pivotally connected to the second base 20 for supporting the portable electric device with a slanted viewing angle a, as shown in FIG. 3b.

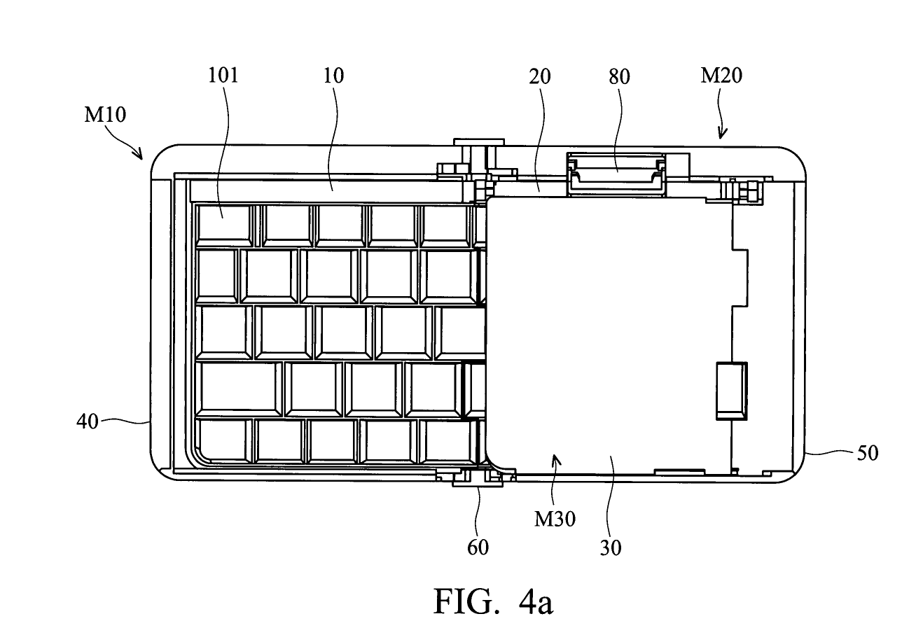

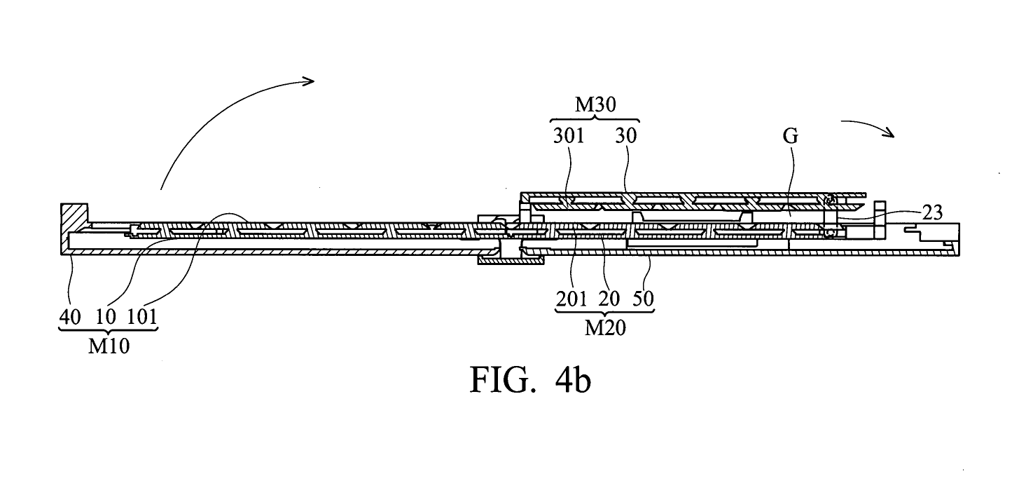

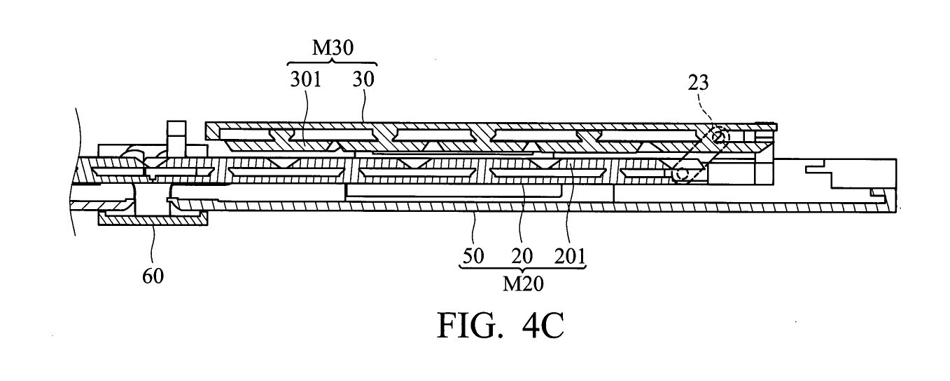

To fold the keyboard, first, the holder 70 is detached, and the third key module M30 is folded toward the second key module M20 with the second and third key units 201 and 301 face to face, as the arrow shown in FIG. 3c. Specifically, when the second and third key modules M20 and M30 are folded, the link 23 is slanted with respect to the second and third bases 20 and 30 from the state shown in FIG. 4b to the state shown in FIG. 4c, thus reducing the gap G between the second and third key units 201 and 301. In some embodiments, the second and third key units 201 and 301 can contact each other to save more space.

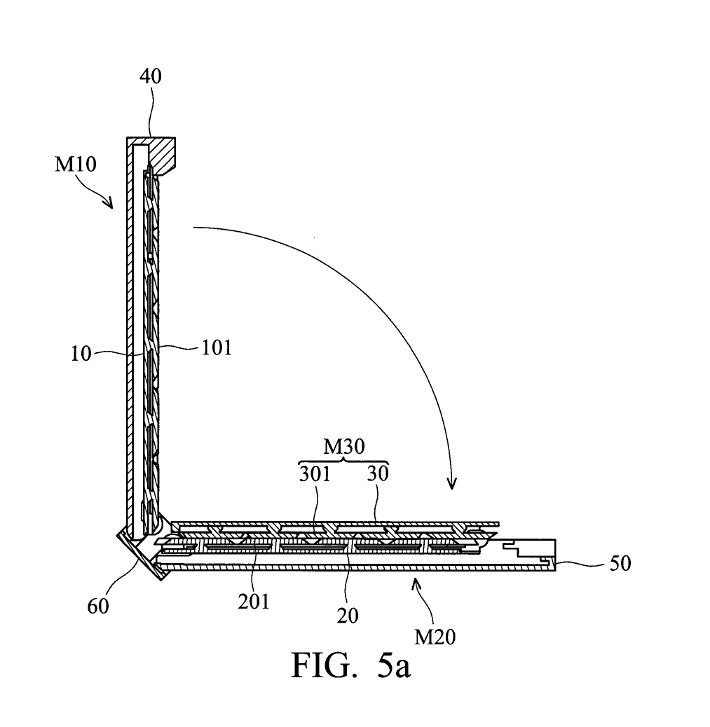

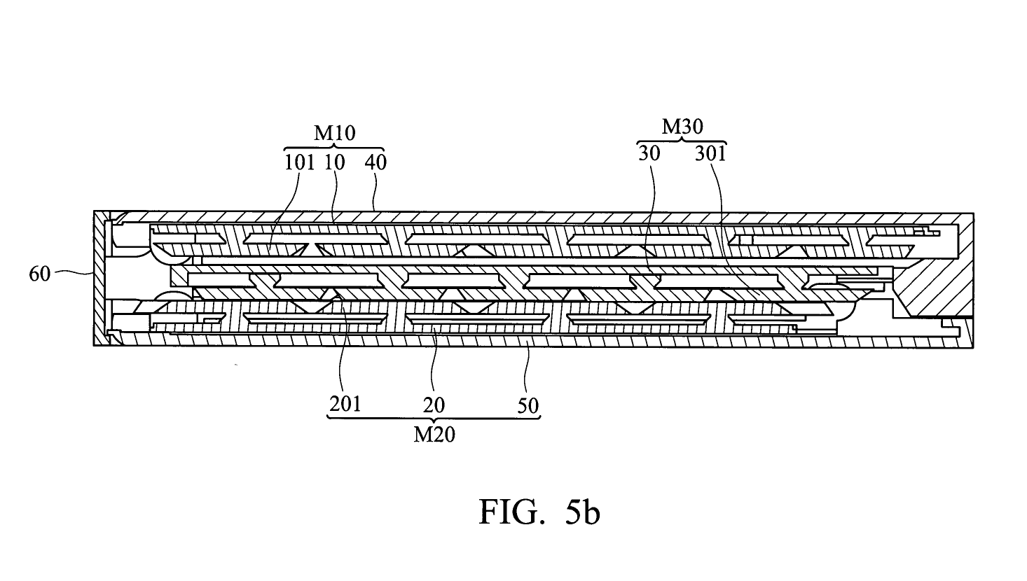

Subsequently, as shown in FIG. 4b, the first key module M10 is folded toward the third key module 30. The keyboard is then completely folded from the state shown in FIG. 5a to the state shown in FIG. 5b. In FIG. 5b, the first, second and third bases 10, 20 and 30 are totally enclosed by the coupler 60, the first and second enclosures 40 and 50. Thus, the first, second and third key units 101, 201 and 301 can be hidden and the keyboard is miniaturized and portable.

When the keyboard is completely folded as shown in FIG. 5b, the third key module M30 is situated between the first and second key modules M10 and M20, wherein the first and third key units 101 and 301 face the second key units 201. Since the link 23 is slanted with respect to the second and third bases 20 and 30, thus reducing the gap between the second and third key units 201 and 301, and the size of the coupler 60 and the keyboard can be greatly minimized.

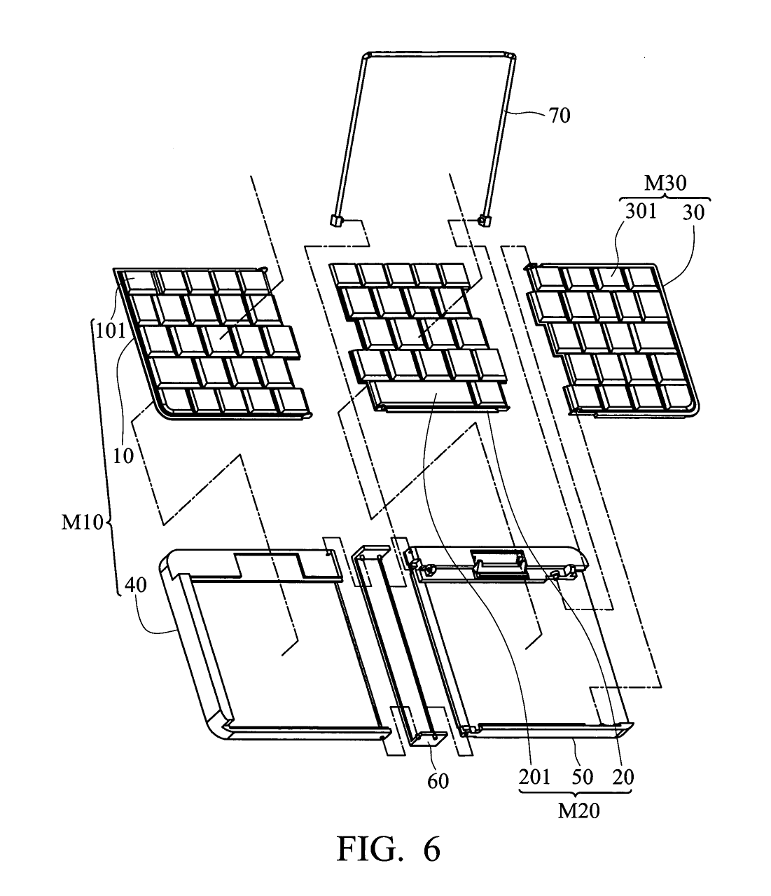

Referring to FIG. 6, another exemplary embodiment of a folding keyboard with a triple-fold structure primarily comprises a first key module M10, a second key module M20, a third key module M30, a coupler 60, a holder 70. The first key module M10 comprises a first enclosure 40, a first base 10 and a plurality of first key units 101 disposed on the first base 10. The second key module M20 comprises a second enclosure 50, a second base 20 and a plurality of second key units 201 disposed on the second base 20. The third key module M30 comprises a third base 30 and a plurality of third key units 301 disposed on the third base 30. The first and second bases 10 and 20 are respectively disposed in the first and second enclosures 40 and 50. The holder 70 is pivotally connected to the second key module M20. When the keyboard is unfolded, the first, second and third key modules M10, M20 and M30 are substantially situated on the same plane.

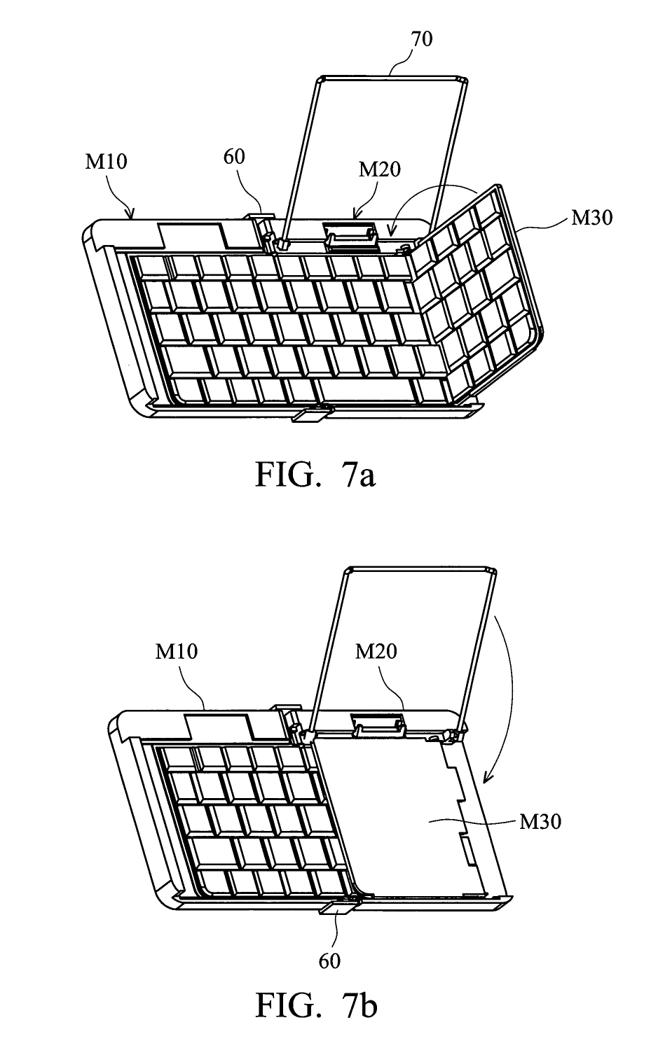

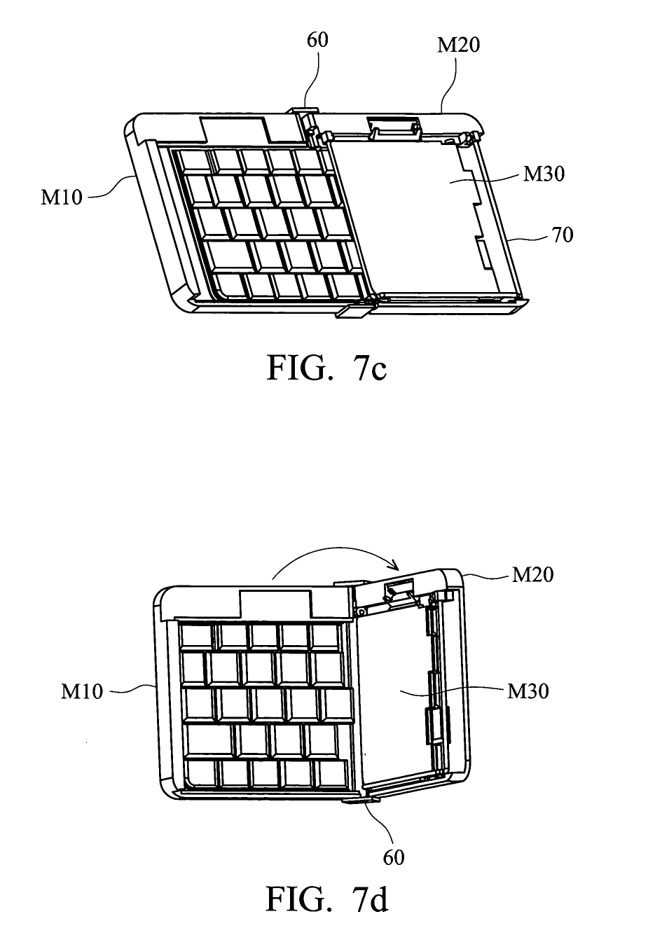

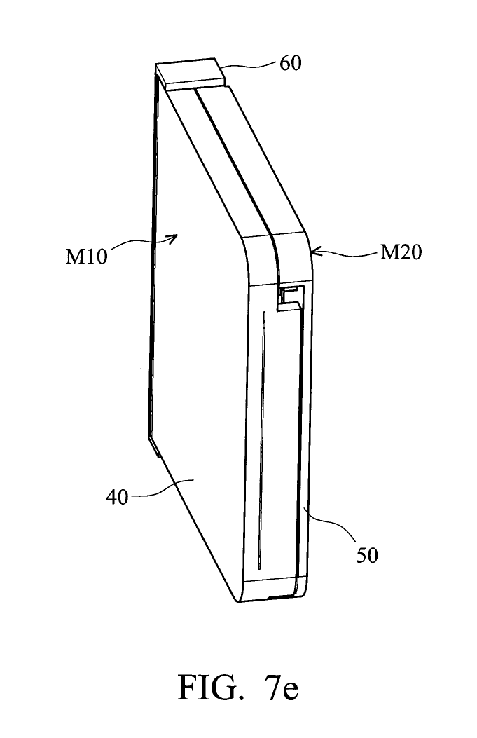

As shown in FIG. 6, the first and second key modules M10 and M20 are pivotally connected via the coupler 60, and the second key module M20 is pivotally connected to the third key module M30. To fold the keyboard, the third key module M30 is folded toward the second key module M20 from the state shown in FIG. 7a to the state shown in FIG. 7b. Subsequently, the holder 70 is folded toward the second key module M20 from the state shown in FIG. 7b to the state shown in FIG. 7c.

Finally, the first key module M10 is folded toward the second and third key modules M20 and M30 as shown in FIG. 7d. As shown in FIG. 7e, the keyboard is completely folded with the third key module M30 enclosed by the coupler 60, the first and second key modules M10 and M20 such that the keyboard is miniaturized and portable. Specifically, the first and third key units 101 and 301 face the second key units 201 when the keyboard is completely folded.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

1. A keyboard, comprising:
a first key module;
a second key module pivotally connected to the first key module; and
a third key module pivotally connected to the second key module, wherein the third key module is situated between the first and the second key modules when the keyboard is folded, and the first, second and third key modules are situated substantially on the same plane when the keyboard is unfolded.

2. The keyboard as claimed in claim 1, wherein the first, second and third key modules comprise a plurality of first, second and third key units respectively, and the first and third key units face the second keys when the keyboard is folded.

3. The keyboard as claimed in claim 2, wherein the first key module further comprises a first enclosure and a first base with the first key units disposed thereon, and the first base is pivotally disposed in the first enclosure.

4. The keyboard as claimed in claim 2, wherein the second key module further comprises a second enclosure and a second base with the second key units disposed thereon, and the second base is pivotally disposed in the second enclosure.

5. The keyboard as claimed in claim 1 further comprises a connector disposed on the second key module for electrically connecting an electric device.

6. The keyboard as claimed in claim 1 further comprises a holder connected to the second key module for supporting an electric device.

7. The keyboard as claimed in claim 3 further comprises a link pivotally connecting the second and third key modules.

8. The keyboard as claimed in claim 4 further comprises a link pivotally connecting the second and third key modules.

9. The keyboard as claimed in claim 8, wherein the link is inclined with respect to the second base.

10. The keyboard as claimed in claim 3 further comprises a coupler pivotally connecting the first and second key modules.

11. The keyboard as claimed in claim 10, wherein the coupler comprises a first pivot portion pivotally connecting the first enclosure and a second pivot portion pivotally connecting the first base.

12. The keyboard as claimed in claim 11, wherein the first pivot portion pivotally connects the second enclosure, and the second pivot portion pivotally connects the second base.

13. The keyboard as claimed in claim 4 further comprises a coupler pivotally connecting the first and second key modules.

14. The keyboard as claimed in claim 13, wherein the coupler comprises a first pivot portion pivotally connecting the first enclosure and a second pivot portion pivotally connecting the first base.

15. The keyboard as claimed in claim 14, wherein the first pivot portion pivotally connects the second enclosure, and the second pivot portion pivotally connects the second base.

16. The keyboard as claimed in claim 2, wherein the first key module further comprises a first ragged edge formed by the first key units, and the second key module further comprises a second ragged edge formed by the second key units, corresponding to first ragged edge.

17. The keyboard as claimed in claim 16, wherein the second key module further comprises a third ragged edge formed by the second key units, and the third key module further comprises a fourth ragged edge formed by the third key units, corresponding to third ragged edge.
